(19) United States
(12) Patent Application Publication
(10) Pub. No.: US 2007/0098030 A1
(43) Pub. Date: May 3, 2007

(54) Nitride semiconductor laser device and method of manufacturing the same

(75) Inventors: Kyoung-ho Ha, Seoul (KR); Han-youl Ryu, Suwon-si (KR)

Correspondence Address: BUCHANAN, INGERSOLL & ROONEY PC, POST OFFICE BOX 1404, ALEXANDRIA, VA, 22313-1404, US

(73) Assignee: Samsung Electronics Co., Ltd., Suwon-si (KR)

(21) Appl. No.: 11/591,515

(22) Filed: Nov. 2, 2006

(30) Foreign Application Priority Data
Nov. 3, 2005 (KR) 10-2005-0105061

(51) Int. Cl. H01S 5/00

(52) U.S. Cl. 372/43.01

(57) ABSTRACT

A semiconductor laser device is provided. The semiconductor laser device includes a substrate, and an n-material layer, an n-clad layer, an n-light waveguide layer, an active region, a nitride semiconductor layer, a metal layer and a metal-based clad layer sequentially formed on the substrate. The metal layer and the metal-based clad layer have a ridge shape and a current blocking layer is formed on sidewalls of the metal layer and the metal-based clad layer and an exposed surface of the nitride semiconductor layer. A p-electrode layer is formed on the ridge shaped metal layer and the current blocking layer. The semiconductor laser device uses the metal-based clad layer instead of AlₓIn_{y}Ga_{1-x-y}N-based p-clad layer, thus preventing degradation of the active region. The semiconductor laser device also includes the thin metal layer between the metal-based clad layer and a p-GaN material of the nitride semiconductor layer, thus reducing contact resistance therebetween. Thus, it is possible to fabricate a high power, low voltage semiconductor laser device having a visible light wavelength.

### CROSS-REFERENCE TO RELATED PATENT APPLICATION

This application claims the benefit of Korean Patent Application No. 10-2005-0105061, filed on Nov. 3, 2005, in the Korean Intellectual Property Office, the disclosure of which is incorporated herein in its entirety by reference.

### BACKGROUND OF THE DISCLOSURE

1. Field of the Disclosure

The present disclosure relates to a semiconductor laser device and a method of manufacturing the semiconductor laser device, and more particularly, to a semiconductor laser device using a metal contact layer and a conductive metal-based material as a clad layer instead of an AlGaN-based material and a method of fabricating the same.

2. Description of the Related Art

A semiconductor laser device using GaN not only is emerging as a promising light source for an optical system for recording and/or reproducing a high-density optical information storage medium such as a blu-ray disc (BD) or a high definition digital versatile disc (HD-DVD) that are next-generation DVD technologies, but is also receiving attention as a new blue and green laser light source in laser display fields.

FIG. 1 is a cross-sectional view of a typical semiconductor laser diode. Referring to FIG. 1, the typical semiconductor laser diode (LD) includes a semiconductor substrate 10, and an AlₓIn_{y}Ga_{1-x-y}N buffer layer 20, an n-AlₓGa₁₋ₓN-based super-lattice (SL) or n-AlₓGa₁₋ₓN clad layer 30, an n-AlₓIn_{y}Ga_{1-x-y}N light waveguide layer 40, an InGaN active layer 50 having a multi quantum well (MQW) structure, a p-AlₓIn_{y}Ga_{1-x-y}N light waveguide layer 60, a p-AlₓGa₁₋ₓN-based super-lattice (SL) or p-AlₓGa₁₋ₓN clad layer 70, a p-contact layer 80, and a p-electrode layer 90 sequentially formed on the semiconductor substrate 10. An n-electrode layer 100 is formed on a portion of the n-AlₓIn_{y}Ga_{1-x-y}N buffer layer 20 where the n-AlₓGa₁₋ₓN-based super-lattice (SL) or n-AlₓGa₁₋ₓN clad layer 30 is not formed. The semiconductor substrate 10 is typically formed of sapphire (Al₂O₃), GaN, AlN or SiC.

When a voltage is applied to the n-electrode layer 100 and the p-electrode layer 90, electrons and holes are injected into a p-n junction of the InGaN active layer 50 to generate laser light. The light waveguide layers 40 and 60 disposed beneath and on the active layer 50 confine laser light generated in the active layer 50. Typically, the amount of In contained in an InGaN active layer must be above 10% in order to manufacture blue and green lasers. However, the conventional growth technique and structure make it difficult to grow an active layer containing a large amount of In.

Although not shown in FIG. 1, the semiconductor laser diode may further include an electron blocking layer (EBL) overlying the active layer 50. The p-AlₓIn_{y}Ga_{1-x-y}N light waveguide layer 60 formed on the active layer 50 may have a thickness greater than about 0.5 μm. Thus, because the thick p-AlₓIn_{y}Ga_{1-x-y}N light waveguide layer 60 is grown at a high temperature above 900° C. for an extended time after the growth of the active layer 50 containing a large amount of In, the active layer 50 suffers degradation or local segregation of In. The degradation or segregation becomes more severe for a LD of the visible light wavelength having a larger amount of In and a lower growth temperature of the active layer. Further, the active layer 50 tends to be strained or cracked due to a large amount of Al or a large thickness of the clad layer 70, thus increasing the magnitude of a driving voltage.

### SUMMARY OF THE DISCLOSURE

The present invention may provide a nitride semiconductor laser device using an AlₓInyGa_{1-x-y}N-based clad layer designed to eliminate degradation and local segregation of an active layer.

According to one aspect of the present invention, there may be provided a semiconductor laser device using a metal layer and a metal-clad layer formed on the metal layer instead of an AlₓIn_{y}Ga_{1-x-y}N clad layer.

The semiconductor laser device includes a substrate, and an n-material layer, an n-clad layer, an nitride semiconductor layer (n-light waveguide layer), an active region, a nitride semiconductor layer (p-light waveguide layer), a metal layer and a metal-based clad layer sequentially formed on the substrate.

The metal layer and the metal-based clad layer having a ridge shape should be formed of a material with a low optical absorption coefficient K in order to prevent loss of laser light generated in the active layer when being confined. In particular, the metal layer may be formed of a low contact resistance material.

Table 1 shows refractive index n, optical absorption coefficient K, and contact resistance ρ for a metal-based material. As evident from the Table 1, because an ITO (InSnO) material possesses a coefficient but higher lower absorption contact resistance than Pd or Pt, use of an ITO layer directly on the nitride semiconductor layer instead of an AlxGa1-xN-based SL or AlxGa1-xN clad layer increases the vertical resistance of the semiconductor laser device, thus resulting in an increase in the driving voltage. Thus, it is necessary to form a contact layer of Pd or Pt with low contact resistance between the p-light waveguide layer and the ITO layer.

TABLE 1

| Metal-based | Refractive index | Optical absorption | Contact resistance |
|---|---|---|---|
| material | (n @420 nm) | (K) | (μΩ-cm2) |
| ITO | 2.1 | 0.04 | 300 |
| Pd | 1.3 | 2.9 | 100 |
| Pt | 1.7 | 2.8 | 100 |

Thus, when the conductive metal oxide or conductive metal nitride is used as a metal-based clad layer, the metal layer is thinly formed to act as a metal contact layer between the semiconductor layer and the metal-based clad layer.

In this instance, the metal layer may be formed to a thickness of approximately 1 to 100 nm using at least one of a metal selected from the group consisting of palladium (Pd), platinum (Pt), nickel (Ni), gold (Au), ruthenium (Ru), silver (Ag) and lanthanide series metals and an alloy or solid solution containing at least one of the metals.

The metal layer has at least one layer of the selected metal or an alloy or solution containing at least one of the metals. The metal-based clad layer is formed of conductive metal oxide or conductive metal nitride. In order to use the conductive metal oxide or conductive metal nitride as a clad layer instead of an AlGaN-based material, the metal oxide or nitride should have higher refractive index n and lower optical absorption coefficient K than a portion formed on the sidewalls of a ridge.

The metal-based clad layer may be formed of conductive metal oxide consisting of oxygen (O) and at least one metal selected from the group consisting of indium (In), tin (Sn), zinc (Zn), gallium (Ga), cadmium (Cd), magnesium (Mg), beryllium (Be), silver (Ag), molybdenum (Mo), vanadium (V), copper (Cu), iridium (Ir), rhodium (Rh), Ru, tungsten (W), cobalt (Co), Ni, manganese (Mn), aluminum (Al) and lanthanide (Ln) series metals.

The conductive metal oxide may contain the three elements Ga, In, and Zn, together with oxygen, or the four elements Ga, In, Sn, and Zn, together with oxygen, as its main elements. The conductive metal nitride contains titanium (Ti) and nitrogen (N).

The metal-based clad layer 170 may be formed of metal nitride containing Ti and nitrogen (N) in a thickness of approximately 50 to 1,000 nm.

An additional element may be used to adjust the electrical characteristics of the metal-based clad layer 170 of conductive metal oxide or conductive metal nitride.

The additional element may be at least one metal selected from the group consisting of Mg, Ag, Zn, scandium (Sc), hafnium (Hf), zirconium (Zr), tellurium (Te), selenium (Se), tantalum (Ta), W, niobium (Nb), Cu, Si, Ni, Co, Mo, chrome (Cr), Mn, mercury (Hg), praseodymium (Pr), and lanthanide (Ln) series metals.

In order to form the ridge, a portion of the metal layer and the metal-based clad layer excluding the ridge may be etched down to a surface of the active region.

The semiconductor laser device may further include a current blocking layer covering the sidewalls of the ridge and an exposed surface of the nitride semiconductor layer of a nitride semiconductor material.

The current blocking layer is formed of an insulating dielectric material. In this case, a p-electrode layer may be formed on the current blocking layer and the ridge-shaped metal-based clad layer.

The semiconductor laser device includes the n-material layer and the n-clad layer between the substrate and the active region. The n-material layer has a stepped structure and an n-electrode layer is formed on the n-material layer. When the substrate is made of GaN, the n-electrode is formed beneath the GaN substrate.

In another embodiment, a semiconductor laser device may use a single metal layer as a clad layer instead of an AlₓIn_{y}Ga_{1-x-y}N-based clad layer. The metal layer is formed in a thickness less than approximately 1,000 nm.

The semiconductor laser device may include a substrate, and an n-material layer, an n-clad layer, an nitride semiconductor layer, an active region and a metal layer sequentially formed on the substrate. The n-material layer has a stepped structure, on which an n-electrode layer is formed. The active region has a single quantum well (SQW) or multiple quantum well (MQW) structure. The semiconductor laser device may further include a nitride semiconductor layer formed between the active region and the metal layer. The nitride semiconductor layer may be formed in a thickness of approximately 1 to 500 nm.

### BRIEF DESCRIPTION OF THE DRAWINGS

The above and other features and advantages of the present invention are illustrated in detailed exemplary embodiments thereof with reference to the attached drawings in which:

FIG. 1 is a cross-sectional view of a conventional semiconductor laser device;

FIG. 2 is a cross-sectional view of a semiconductor laser diode (LD) according to an embodiment of the present invention;

FIG. 3 is a graph illustrating the modal-loss and optical confinement factor (OCF) with respect to an ITO thickness for a semiconductor LD according to an embodiment of the present invention with a metal layer of Pd and an metal-based clad layer of ITO; and

FIG. 4 is a cross-sectional view of a semiconductor LD according to another embodiment of the present invention.

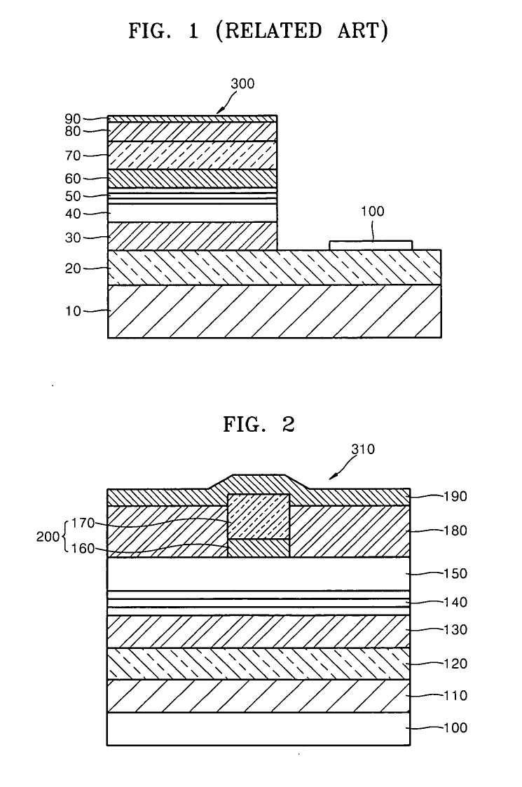

### DETAILED DESCRIPTION OF EXEMPLARY EMBODIMENTS

A semiconductor laser device and method of fabricating the same according to preferred embodiments of the present invention will now be described more fully with reference to the accompanying drawings. The invention may, however, be embodied in many different forms and should not be construed as being limited to the embodiments set forth herein. That is, a semiconductor laser device according to the present invention may have various other stack structures than described herein.

FIG. 2 is a cross-sectional view of a semiconductor laser device according to an embodiment of the present invention with a metal layer and a metal-based clad layer. Referring to FIG. 2, the semiconductor laser device includes a substrate 100, and an n-material layer 110, an n-clad layer 120, an n-light waveguide layer 130, an active region 140, a nitride semiconductor layer (p-waveguide layer) 150, a metal layer 160 and a metal-based clad layer 170 sequentially formed on the substrate 100. The metal layer 160 and the metal-based clad layer 170 have a ridge shape. The semiconductor laser device further includes a current blocking layer 180 that is formed on sidewalls of the metal layer 160, and the metal-based clad layer 170 and an exposed surface of the nitride semiconductor layer 150 and a p-electrode layer 190 formed on the metal-based clad layer 170 and the current blocking layer 180.

The substrate 110 may be formed of sapphire (Al₂O₃), silicon carbide (SiC), Si, or gallium nitride (GaN). The n-material layer 110 is formed of a GaN-based III-V nitride semiconductor compound. Although not shown in FIG. 2, the n-material layer 110 may be used as a contact layer contacting an n-electrode layer. For example, the n-material layer 110 may be formed of n-GaN. The n-clad layer 120 may be formed of GaN/AlGaN superlattice (SL) or other semiconductor compound that can induce lasing. For example, the n-clad layer 120 may be formed of n-AlGaN/n-GaN, n-AlGaN/GaN or AlGaN/n-GaN, or n-AlGaN.

The n-light waveguide layer 130 and the nitride semiconductor layer 150 may be formed of a GaN-based Ill-V semiconductor compound. For example, the n-light waveguide layer 130 and the nitride semiconductor layer 150 may be formed of n-AlₓIn_{y}Ga_{1-x-y}N and p-AlₓIn_{y}Ga_{1-x-y}N, respectively.

The active region 140 may be formed of any material that can induce lasing and have a single quantum well (SQW) or multi-quantum well (MQW) structure.

For example, the active region 140 may be made of GaN, AlGaN, InGaN or AllnGaN. An electron blocking layer (EBL; not shown) of p-AlₓIn_{y}Ga_{1-x-y}N may be formed between the active region 140 and the nitride semiconductor layer 150. The EBL with a larger energy gap than any other crystal layer prevents movement of electrons into a p-semiconductor layer.

The metal-based clad layer 170 may be made of conductive metal oxide or conductive metal nitride. The metal layer 160 is used as a metal contact layer to reduce a contact resistance between the nitride semiconductor layer 150 and the metal-based clad layer 170. In this case, the metal layer 160 is formed to a thickness less than approximately 100 nm.

The metal layer 160 may be formed of a metal selected from the group consisting of palladium (Pd), platinum (Pt), nickel (Ni), gold (Au), ruthenium (Ru), silver (Ag), and lanthanide (Ln) series metals or an alloy or solid solution containing at least one of the metals.

The metal layer 160 has at least one layer of the selected metal or an alloy or solution containing at least one of the metals.

The metal-based clad layer 170 may be formed of conductive metal oxide consisting of oxygen (O) and at least one metal selected from the group consisting of indium (In), tin (Sn), zinc (Zn), gallium (Ga), cadmium (Cd), magnesium (Mg), beryllium (Be), silver (Ag), molybdenum (Mo), vanadium (V), copper (Cu), iridium (Ir), rhodium (Rh), Ru, tungsten (W), cobalt (Co), Ni, manganese (Mn), aluminum (Al), and lanthanide (Ln) series metals. For example, the metal-based clad layer 170 may be formed of conductive metal oxide such as InO, AgO, CuO, In₁₋ₓSnₓO, ZnO, CdO, SnO, NiO, CuₓIn₁₋ₓO, Mg₁₋ₓInₓO, Mg₁₋ₓZnₓO, Be₁₋ₓZnₓO, Zn₁₋ₓBaₓO, Zn₁₋ₓCaₓO, Zn₁₋ₓCdₓO, Zn₁₋ₓSeₓO, Zn₁₋ₓSₓO, or Zn₁₋ₓTeₓO.

The metal-based clad layer 170 may also contain the three elements Ga, In, and Zn, together with oxygen, or the four elements Ga, In, Sn and Zn, together with oxygen, as its main elements.

The metal-based clad layer 170 may be formed of metal nitride containing Ti and nitrogen (N) in a thickness of approximately 50 to 1,000 nm. An additional element may be used to adjust the electrical characteristics of the metal-based clad layer 170 of conductive metal oxide or conductive metal nitride to form a p-oxide layer or p-nitride layer.

The additional element may be at least one metal selected from the group consisting of Mg, Ag, Zn, scandium (Sc), hafnium (Hf), zirconium (Zr), tellurium (Te), selenium (Se), tantalum (Ta), W, niobium (Nb), Cu, Si, Ni, Co, Mo, chrome (Cr), Mn, mercury (Hg), praseodymium (Pr), and lanthanide (Ln) series metals.

When the semiconductor laser device according to the present invention has a ridge waveguide structure, the ridge 200 may be formed according to the following steps.

First, after sequentially forming the n-material layer 110, the n-clad layer 120, the n-light waveguide layer 130, the active region 140, the nitride semiconductor layer 150, the metal layer 160 and the metal-based clad layer 170 on the substrate 100, the resulting structure is etched down to a surface of the n-material layer 110 in order to form a stepped structure. The stepped structure is created in order to form the n-electrode layer on an exposed portion of the n-material layer 110.

When the substrate 100 is made of GaN, the n-electrode layer may underlie the substrate 100. A portion of the metal layer 160 and the metal-based clad layer 170 excluding the ridge 200 is etched down to a surface or portion of the nitride semiconductor layer 150 so as to expose a portion of the nitride semiconductor layer 150, thereby forming the ridge 200. Because a technique for forming a ridge waveguide structure or ridge structure is well known in the art, a detailed explanation thereof is not included.

A current blocking layer 180 is formed on the exposed surface of the nitride semiconductor layer 150 and both sidewalls of the ridge 200. The current blocking layer 180 may be formed of an insulating dielectric material, such as oxide or nitride containing at least one element selected from the group consisting of Si, Al, Zr, Hf, Mn, Ti, and Ta. For example, the insulating dielectric material may be SiO₂, SiNₓ, HfOₓ, AlN, Al₂O₃, TiO₂, ZrO, MnO or Ta₂O₅.

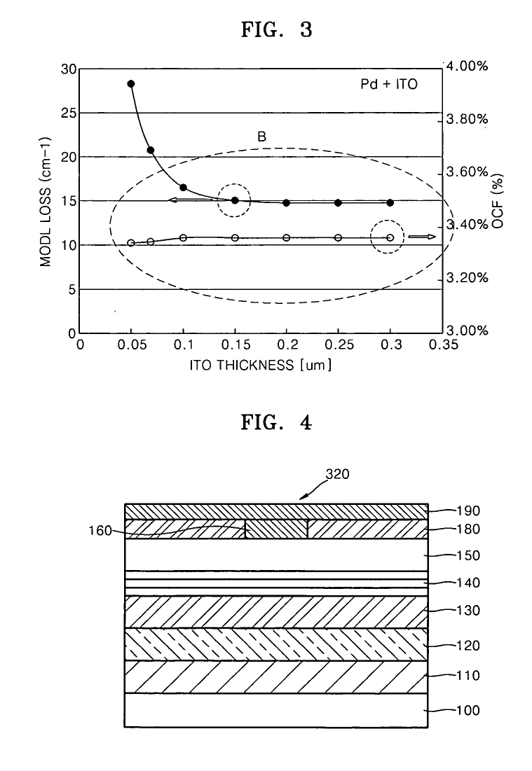

FIG. 3 is a graph illustrating the modal-loss and optical confinement factor (OCF) with respect to an ITO thickness for the semiconductor laser device of FIG. 2.

In the semiconductor laser device, the metal-based clad layer 170 is formed of an ITO material. The metal layer 160 is formed of Pd to reduce a contact resistance between p-GaN in the nitride semiconductor layer 150 and ITO material in the metal-based clad layer 170.

As evident from FIG. 3, modal loss has a value less than 15 cm⁻¹ and OCF has a value greater than about 3.3% when an ITO thickness is greater than 0.1 μm. As described above, a typical InGaN semiconductor LD has a modal loss of about 20 to 60 cm⁻¹. The semiconductor laser device using the Pd metal layer and the ITO metal-based clad layer has a modal loss that is within the effective range over almost the entire region indicated by B. Further, because the semiconductor laser device has OCF of about 3.3%, it can function adequately as a LD.

FIG. 4 is a cross-sectional view illustrating a stack structure of a semiconductor laser device according to another embodiment of the present invention.

Referring to FIG. 4, the semiconductor laser device includes a substrate 100, and an n-material layer 110, an n-clad layer 120, an n-light waveguide layer 130, an active region 140, a nitride semiconductor layer 150 and a metal layer 160 sequentially formed on the substrate 100. The metal layer 160 has a ridge shape and a current blocking layer 180 is formed on sidewalls of the metal layer 160 and an exposed surface of the nitride semiconductor layer 150. A p-electrode layer 190 is formed on the ridge shaped metal layer and the current blocking layer 180.

The ridge-shaped metal layer 160 may have a thickness of approximately 50 to 1,000 nm to simultaneously act as a contact layer, a clad layer, and a waveguide.

Other layers in the semiconductor laser device have the same material and thickness as their counterparts in the semiconductor laser device of FIG. 2.

The semiconductor laser device of FIG. 4 with the Pd metal layer 160 has a modal loss of 30 cm⁻¹ and an OCF of about 3%. Since a typical InGaN semiconductor LD has a modal loss of about 20 to 60 cm⁻¹, the semiconductor laser device using the single Pd metal layer as a clad layer has a modal loss that is within the effective range. Further, because the semiconductor laser device has an OCF of 2 to 3%, it can function adequately as a LD.

While in the above description, the semiconductor laser devices of FIGS. 2 and 4 have a ridge structure, they may have various other structures.

A semiconductor laser device of the present invention can achieve a sufficient optical confinement effect without using an AlₓGa₁₋ₓN-based SL or n-AlₓGa₁₋ₓN material as a clad layer, thus enabling fabrication of a high power nitride semiconductor laser device having a visible light wavelength.

The semiconductor laser device according to the present invention uses a metal layer/metal-based clad layer or a single metal layer as a p-semiconductor clad layer, thus preventing degradation of an active region and segregation of In. The semiconductor laser device also includes a metal layer between a metal-based clad layer and a semiconductor layer overlying the active region, thus reducing a contact resistance therebetween. Furthermore, the present invention allows fabrication of a high power semiconductor laser device with a visible light wavelength.

Thus, the present invention enables growth of active layer containing approximately 10% of In or more, thereby enabling the fabrication of lasers with visible light wavelengths including blue and green wavelengths.

The use of a metal-based clad layer instead of AlₓGa₁₋ₓN-based SL or n-AlₓGa₁₋ₓN-based p-clad layer can simplify the manufacturing process of a semiconductor laser device.

The present invention can eliminate problems such as a strain and a crack in an active region and an increase in driving voltage caused by the use of a large amount of Al and a thick clad layer in a conventional semiconductor laser to enhance the optical confinement effect.

The use of a metal layer or metal layer/metal-based clad layer instead of all or a portion of p-semiconductor clad layer acting as a main source of resistance can significantly reduce a series resistance during device operation. This is not only advantageous for high temperature high power operation due to a decrease in Joule heat but also achieves an improved optical confinement effect and modal gain.

While the present invention has been particularly shown and described with reference to exemplary embodiments thereof, it will be understood by those of ordinary skill in the art that various changes in form and details may be made therein without departing from the spirit and scope of the present invention as defined by the following claims.

What is claimed is:

1. A semiconductor laser device comprising:
an active region;
a nitride semiconductor layer formed on the active region; and
a ridge-shaped metal layer formed on the nitride semiconductor layer.

2. The device of claim 1, wherein the metal layer has a thickness less than approximately 1,000 nm.

3. The device of claim 1, further comprising a current blocking layer covering sidewalls of the ridge-shaped metal layer and a surface of the nitride semiconductor layer exposed on both sides of the ridge-shaped metal layer.

4. The device of claim 1, wherein the active region has a single quantum well (SQW) or multiple quantum well (MQW) structure.

5. The device of claim 4, wherein the quantum well is made from one of GaN, AlGaN, InGaN and AllnGaN.

6. The device of claim 1, wherein the nitride semiconductor layer is formed in a thickness of approximately 1 to 500 nm.

7. The device of claim 1, further comprising a ridge-shaped metal-based clad layer formed on the metal layer.

8. The device of claim 7, wherein the metal-based clad layer is made of conductive metal oxide.

9. The device of claim 7, wherein the metal-based clad layer is made of conductive metal nitride.

10. The device of claim 7, further comprising a current blocking layer formed on sidewalls of the ridge-shaped metal layer and metal-clad layer and a surface of the nitride semiconductor layer exposed on both sides of the ridge-shaped metal layer and metal-clad layer.

11. The device of claim 3, wherein the current blocking layer is formed of at least one of an insulating dielectric material and oxide containing at least one element selected from the group consisting of silicon (Si), aluminum (Al), zirconium (Zr), tantalum (Ta), Hf, Mn, and titanium (Ti).

12. The device of claim 7, wherein the metal layer is formed in a thickness of approximately 1 to 100 nm.

13. The device of claim 1, wherein the metal layer is formed of at least one of a metal selected from the group consisting of palladium (Pd), platinum (Pt), nickel (Ni), gold (Au), ruthenium (Ru), silver (Ag), and lanthanide series metals and an alloy or solid solution containing at least one of the metals.

14. The device of claim 1, wherein the metal layer has at least one layer formed of a metal or an alloy or solution containing at least one metal selected from the group consisting of palladium (Pd), platinum (Pt), nickel (Ni), gold (Au), ruthenium (Ru), silver (Ag), and lanthanide series metals.

15. The device of claim 7, wherein the metal-based clad layer is formed in a thickness of approximately 50 to 1,000 nm.

16. The device of claim 8, wherein the conductive metal oxide consists of oxygen (O) and at least one metal selected from the group consisting of indium (In), tin (Sn), zinc (Zn), gallium (Ga), cadmium (Cd), magnesium (Mg), beryllium (Be), Ag, molybdenum (Mo), vanadium (V), copper (Cu), iridium (Ir), rhodium (Rh), Ru, tungsten (W), cobalt (Co), Ni, manganese (Mn), Al, and lanthanide series metals.

17. The device of claim 8, wherein the conductive metal oxide contains In and Sn together with oxygen as its main elements.

18. The device of claim 9, wherein the conductive metal nitride contains titanium (Ti) and nitrogen (N).

19. The device of claim 7, wherein the metal-based clad layer further includes an additional element to adjust the electrical characteristics.

20. The device of claim 19, wherein the additional element is at least one selected from the group consisting of Mg, Ag, Zn, scandium (Sc), hafnium (Hf), Zr, tellurium (Te), selenium (Se), Ta, W, niobium (Nb), Cu, Si, Ni, Co, Mo, chrome (Cr), Mn, mercury (Hg), praseodymium (Pr), and lanthanide (Ln) series metals.

21. A method of fabricating a semiconductor laser device comprising:
forming an active region;
forming a nitride semiconductor layer on the active region;
forming a metal layer on the light waveguide layer;
etching the metal layer to form a ridge; and
forming a current blocking layer covering sidewalls of the ridge and a surface of the nitride semiconductor layer exposed on both sides of the ridge.

22. The method of claim 21, further comprising:
forming a metal-based clad layer on the metal layer;
etching the metal layer and the metal-based clad layer to form a ridge;
forming a current blocking layer covering sidewalls of the ridge and a surface of the nitride semiconductor layer exposed on both sides of the ridge; and
forming a p-electrode layer on the ridge and the current blocking layer.

23. The method of claim 22, wherein the metal-based clad layer is made of one of conductive metal oxide and conductive metal nitride.

24. The device of claim 8, wherein the conductive metal oxide contains In and Sn together with oxygen as its main elements.
